(19) United States
(12) Patent Application Publication
(10) Pub. No.: US 2012/0299178 A1
(43) Pub. Date: Nov. 29, 2012

(54) SEMICONDUCTOR DEVICE

(75) Inventors: Ko KANAYA, Tokyo (JP); Yoshihiro TSUKAHARA, Tokyo (JP)

(73) Assignee: MITSUBISHI ELECTRIC CORPORATION, Tokyo (JP)

(21) Appl. No.: 13/365,302

(22) Filed: Feb. 3, 2012

(30) Foreign Application Priority Data
May 23, 2011 (JP) 2011-114933

(51) Int. Cl. H01L 23/48

(52) U.S. Cl. 257/737; 257/E23.021

(57) ABSTRACT

A semiconductor device includes: a main body chip; a circuit pattern on a front surface of the main body chip and including a first pad; a cap chip including a first recess in a front surface of the cap chip and a second recess in a back surface of the cap chip, the cap chip being joined to the main body chip with the first recess facing the circuit pattern; a second pad on a bottom surface of the first recess of the cap chip; a first metallic member inlaid in the second recess of the cap chip; a first through electrode electrically connecting the second pad to the first metallic member through the cap chip; and a bump electrically connecting the first pad to the second pad.

### BACKGROUND OF THE INVENTION

1. Field of the Invention

The present invention relates to a semiconductor device using microwaves or millimetric-waves, and in particular to a semiconductor device which can release heat efficiently.

2. Background Art

In recent years, semiconductor devices provided as high-output amplifiers for radars or communication infrastructures and using a nitride semiconductor have been increased. A nitride semiconductor has a high saturated electron velocity and a high insulation breakdown electric field and is, therefore, promising as a material for radiofrequency high-output devices.

In a conventional package for radiofrequency high-output devices, a semiconductor chip is die-bonded to a base member and a radiofrequency signal is input to or output from the semiconductor chip via a wire or a lead. A lid is provided on an upper portion of the package to hermetically encapsulate the semiconductor chip. Heat generated in transistors is released through the base member. However, degradation in radiofrequency characteristics is caused by a parasitic component due to a wire, a lead or the like. Also, the manufacturing cost is largely increased by the package material cost and the assembly cost.

To solve these problems, methods of packaging on the wafer level are being briskly developed (see, for example, Japanese Patent Laid-Open No. 2003-204005). A main body wafer on which transistors and peripheral circuits are formed and a cap wafer are joined to each other on the wafer level and the wafers are diced, thus packaging semiconductor chips collectively. After separation into the chips, each chip is mounted on a substrate, with bumps interposed therebetween. Thus, parasitic components and the package cost can be reduced.

### SUMMARY OF THE INVENTION

In the conventional device, however, the effect of releasing heat from a lower portion of the chip is low because such a device is mounted by means of bumps, so that heat cannot be efficiently released, which leads to degradation in device characteristics and reliability. This problem is particularly serious with a radiofrequency high-output device in which a transistor generates a considerable amount of heat.

In view of the above-described problems, an object of the present invention is to provide a semiconductor device which can release heat efficiently.

According to the present invention, a semiconductor device includes: a main body chip; a circuit pattern on a front surface of the main body chip and including a first pad; a cap chip including a first recess in a front surface of the cap chip and a second recess in a back surface of the cap chip, the cap chip being joined to the main body chip with the first recess facing the circuit pattern; a second pad on a bottom surface of the first recess of the cap chip; a first metallic member inlaid in the second recess of the cap chip; a first through electrode connecting the second pad to the first metallic member through the cap chip; and a bump connecting the first pad to the second pad.

The present invention makes it possible to release heat efficiently.

Other and further objects, features and advantages of the invention will appear more fully from the following description.

### BRIEF DESCRIPTION OF THE DRAWINGS

FIG. 1 is a top view of a semiconductor device according to a first embodiment of the present invention.

FIG. 2 is a top view showing the front surface of the main body chip of the device shown in FIG. 1.

FIG. 3 is a bottom view showing the back surface of the main body chip of the device shown in FIG. 1.

FIG. 4 is a sectional view taken along line I-I in FIG. 1.

FIG. 5 is a sectional view taken along II-II in FIG. 1.

FIG. 6 is a sectional view taken along line III-III in FIG. 1.

FIG. 7 is a top view of a semiconductor device according to a second embodiment of the present invention.

FIG. 8 is a sectional view taken along line IV-IV in FIG. 7.

FIG. 9 is a sectional view taken along line V-V in FIG. 7.

FIG. 10 is a top view of a semiconductor device according to a third embodiment of the present invention.

FIG. 11 is a sectional view taken along line VI-VI in FIG. 10.

FIG. 12 is a sectional view of a semiconductor device according to a fourth embodiment of the present invention.

FIG. 13 is a sectional view showing a semiconductor device according to a fifth embodiment of the present invention.

### DETAILED DESCRIPTION OF THE PREFERRED EMBODIMENTS

A semiconductor device according to the embodiments of the present invention will be described with reference to the drawings. The same components will be denoted by the same symbols, and the repeated description thereof may be omitted.

### First Embodiment

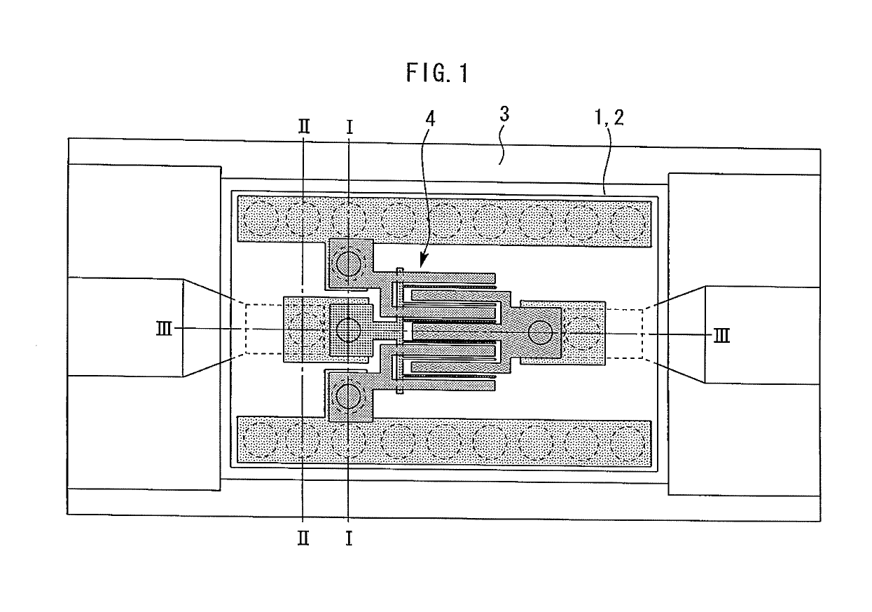

FIG. 1 is a top view of a semiconductor device according to a first embodiment of the present invention. A device having a main body chip 1 and a cap chip 2 joined to each other is mounted on a substrate 3. A circuit pattern 4 is provided on a front surface of the main body chip 1. Although the circuit pattern 4 is covered with the cap chip 2 in actuality, FIG. 1 shows the circuit pattern 4 as seen through the cap chip 2.

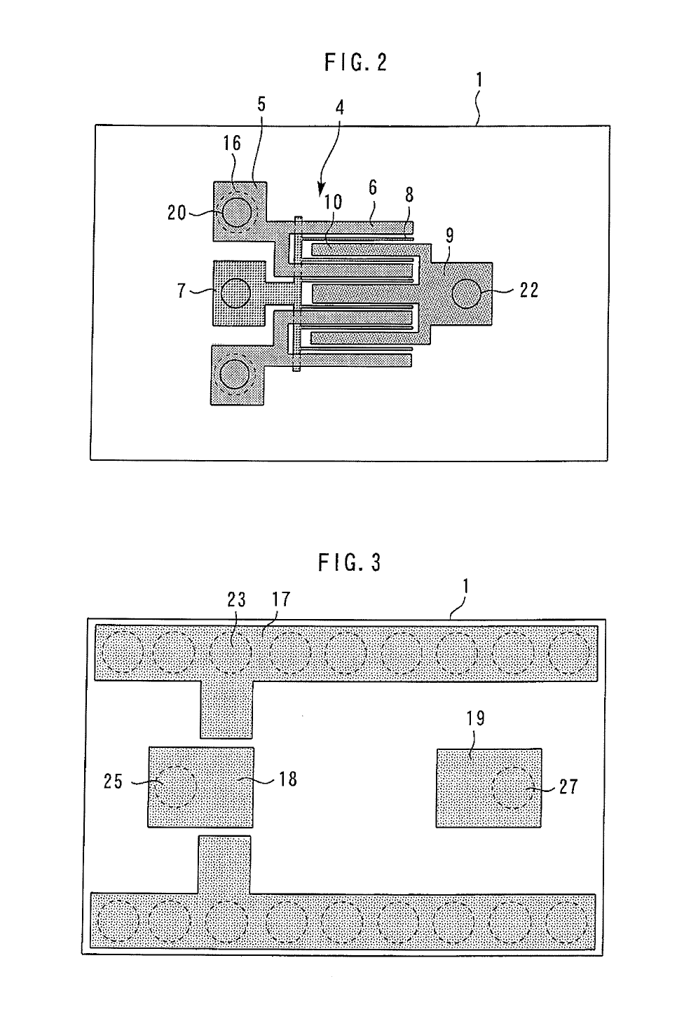

FIG. 2 is a top view showing the front surface of the main body chip of the device shown in FIG. 1. The circuit pattern 4, which is a source-grounded field effect transistor (FET), has a source pad 5, a source electrode 6, a gate pad 7, a gate electrode 8, a drain pad 9 and a drain electrode 10. The circuit pattern 4 also includes a resistor, a metal-insulator-metal (MIM) capacitor, a spiral inductor, wiring, a via hole, an amplifier and an oscillator, though these components are not shown in the figures.

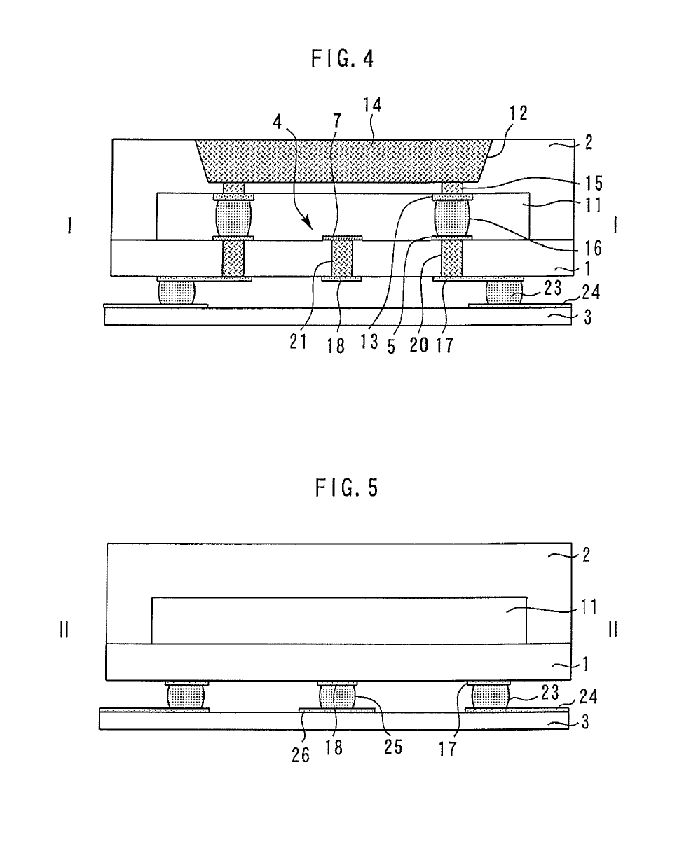

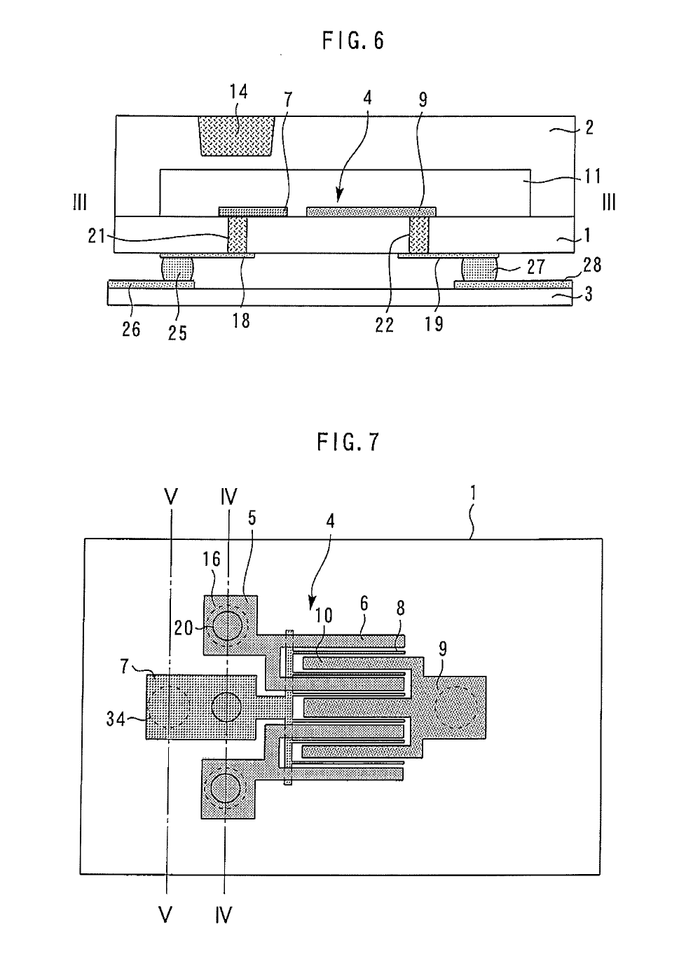

FIG. 3 is a bottom view showing the back surface of the main body chip of the device shown in FIG. 1. FIG. 4 is a sectional view taken along line I-I in FIG. 1. FIG. 5 is a sectional view taken along II-II in FIG. 1. FIG. 6 is a sectional view taken along line III-III in FIG. 1.

A recess 11 is provided in a front surface of the cap chip 2, while a recess 12 is provided in a back surface of the cap chip 2. A pad 13 is provided on a bottom surface of the recess 11 of the cap chip 2. A metallic member 14 is inlaid in the recess 12 of the cap chip 2. A through electrode 15 connects the pad 13 and the metallic member 14 to each other through the cap chip 2.

The cap chip 2 is joined to the main body chip 1, with the recess 11 facing the circuit pattern 4. The source pad 5 on the main body chip 1 and the pad 13 on the cap chip 2 are connected to each other by a bump 16 for releasing heat.

Pads 17, 18, and 19 are provided on a back surface of the main body chip 1. A through electrode 20 connects the source pad 5 and the pad 17 to each other through the main body chip 1. A through electrode 21 connects the gate pad 7 and the pad 18 to each other through the main body chip 1. A through electrode 22 connects the drain pad 9 and the pad 19 to each other through the main body chip 1.

The pad 17 is connected to a ground line 24 on the substrate 3 by means of grounding bumps 23 provided on the chip back surface near the pad 17. The pad 18 is connected to an input signal line 26 on the substrate 3 by means of a bump 25.

The pad 19 is connected to an output signal line 28 on the substrate 3 by means of a bump 27.

An input signal is supplied from the input signal line 26 on the substrate 3 to the gate pad 7 for the transistor via the bump 25, the pad 18 and the through electrode 21. An output signal from the circuit pattern 4 is output from the drain pad 9 to the output signal line 28 on the substrate 3 via the through electrode 22, the pad 19 and the bump 27.

The advantages of the present embodiment will be described. The source pad 5 on the main body chip 1 is connected to the metallic member 14 of the cap chip 2 via the bump 16 for releasing heat, the pad 13 and the through electrode 15. The metallic member 14 serves as a heat sink to release heat generated in the transistor. Release of heat from a chip top portion is thus enabled, so that heat can be efficiently released.

Also, the source pad 5 is connected to the ground line 24 on the substrate 3 via the through electrode 20, the pad 17 and the grounding bumps 23. A grounded heat sink may be provided on the substrate 3 to enable release of heat from a chip bottom portion. Release of heat through the opposite chip surfaces is thus enabled, so that heat can be efficiently released even from a high-output transistor that generates heat at a high rate.

The need for a high-cost package member is eliminated and the assembly cost can be largely reduced. Further, parasitic components due to wires, leads or the like can be reduced and, therefore, degradation in radiofrequency performance can be prevented.

The circuit pattern 4 is hermetically encapsulated with the cap chip 2. Therefore, the device is largely improved in moisture resistance in comparison with a bare chip not having the cap chip 2. If an insulating film for moisture resistance is formed on the circuit pattern 4 on a bare chip, the gain is reduced by a parasitic component due to the film. In the present embodiment, however, a hollow space is formed above the circuit pattern 4, thereby enabling limiting of a reduction in gain in the radiofrequency region due to a parasitic component.

A heat sink may be additionally provided on the metallic member 14 of the cap chip 2 or on a lower portion of the main body chip 1. It is not necessarily required that the main body chip 1 and the cap chip 2 be formed of the same material. However, if the main body chip 1 and the cap chip 2 are formed of the same material, warpage due to a difference in thermal expansion coefficient can be prevented. If a chip protective film is provided on each of the main body chip 1 and the cap chip 2, the chip can be protected against a mechanical impact at the time of mounting. However, an opening is provided in the chip protective film on the metallic member 14 of the cap chip 2. While the description has been made by way of example of a case where the circuit pattern 4 comprises a source-grounded FET, the transistor in the circuit pattern 4 may alternatively be a different field effect transistor, such as a high electron mobility transistor (HEMT), or a bipolar transistor, such as a heterojunction bipolar transistor (HBT). The through electrodes 15 and 20 may be metal film covering only via hole side wall surfaces. However, the parasitic inductance and thermal resistance can be reduced by filling the holes with a metal.

Since mounting on the substrate is performed after forming the through electrode 20, there is a possibility of the through electrode 20 being broken at the time of mounting on the substrate if the bump 23 for connection to the substrate is disposed immediately below the through electrode 20. It is, therefore, preferable to dispose the bump 23 at a position not coinciding with the through electrode 20. On the other hand, since the through electrodes 15 and 20 are formed after joining the main body chip 1 and the cap chip 2 to each other, the bump 16 for connecting the cap may be disposed at the position coinciding with the through electrodes 15 and 20.

### Second Embodiment

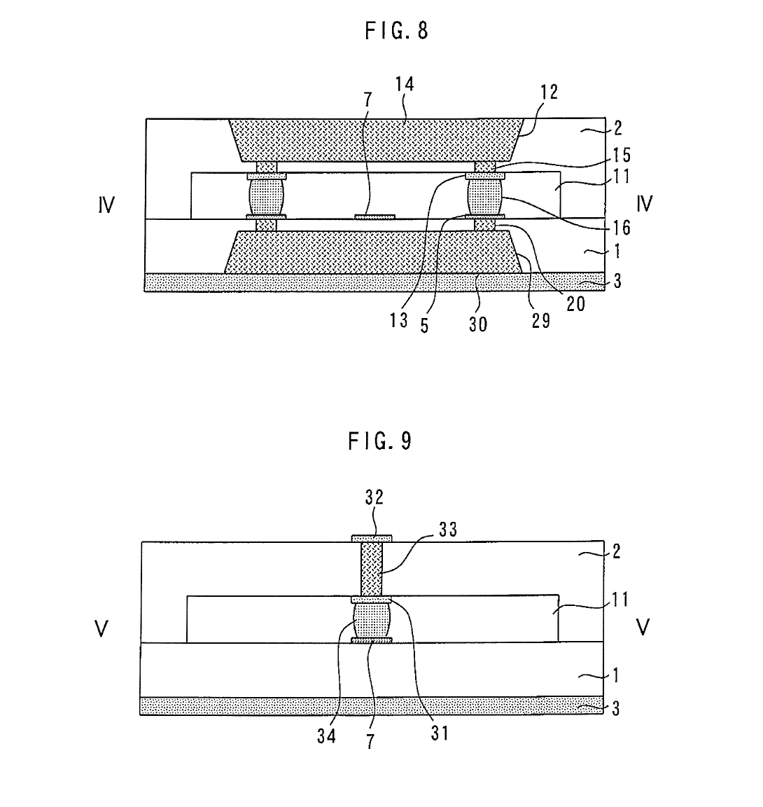

FIG. 7 is a top view of a semiconductor device according to a second embodiment of the present invention. FIG. 8 is a sectional view taken along line IV-IV in FIG. 7. FIG. 9 is a sectional view taken along line V-V in FIG. 7.

A recess 29 is provided on the back surface of the main body chip 1. A metallic member 30 is inlaid in the recess 29 of the main body chip 1. The through electrode 20 connects the source pad 5 and the metallic member 30 to each other through the main body chip 1.

A pad 31 is provided on the bottom surface of the recess 11 of the cap chip 2. A pad 32 is provided on the back surface of the cap chip 2. A through electrode 33 connects the pad 31 and the pad 32 to each other through the cap chip 2. The gate pad 7 and the pad 31 are connected to each other by a bump 34. The same construction is also provided on the drain pad 9 side. Signal input/output is thus enabled to/from the cap chip 2 side. The device having the main body chip 1 and the cap chip 2 joined to each other is directly mounted on the substrate 3 formed of CuW or the like and having a low thermal resistance.

In the present embodiment, the metallic member 30 for releasing heat is also provided on the main body chip 1 side to enable direct release of heat from the main body chip 1 to the substrate 3. Also, a desired moisture resistance of the circuit pattern 4 on the main body chip 1 can be secured.

### Third Embodiment

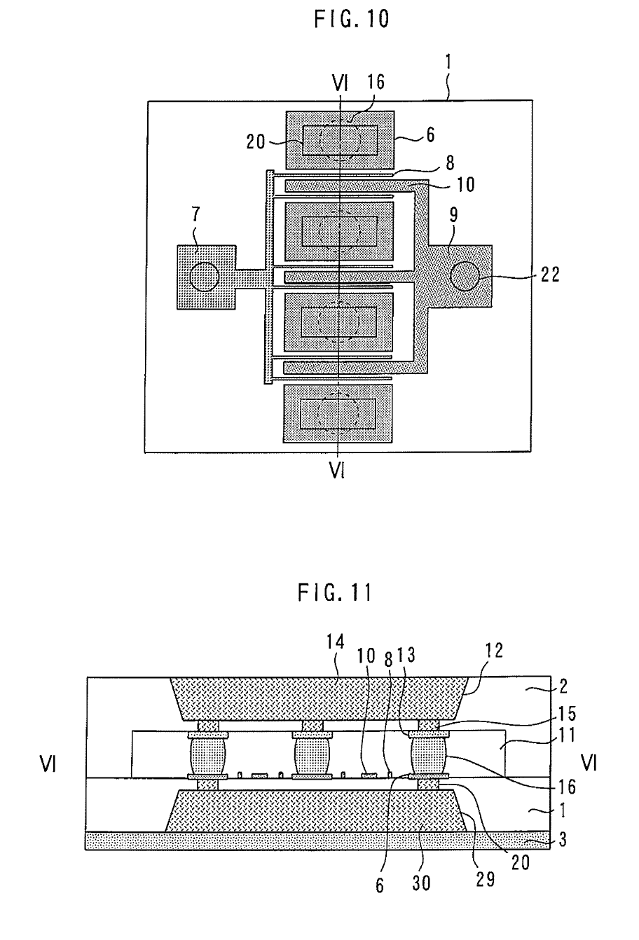

FIG. 10 is a top view of a semiconductor device according to a third embodiment of the present invention. FIG. 11 is a sectional view taken along line VI-VI in FIG. 10. The through electrode 20 is disposed right below the source electrode 6, and the bump 16 is disposed right above the source electrode 6. Thus, heat is released right above and below the transistor, so that the effect of releasing heat is improved in comparison with the first and second embodiments.

### Fourth Embodiment

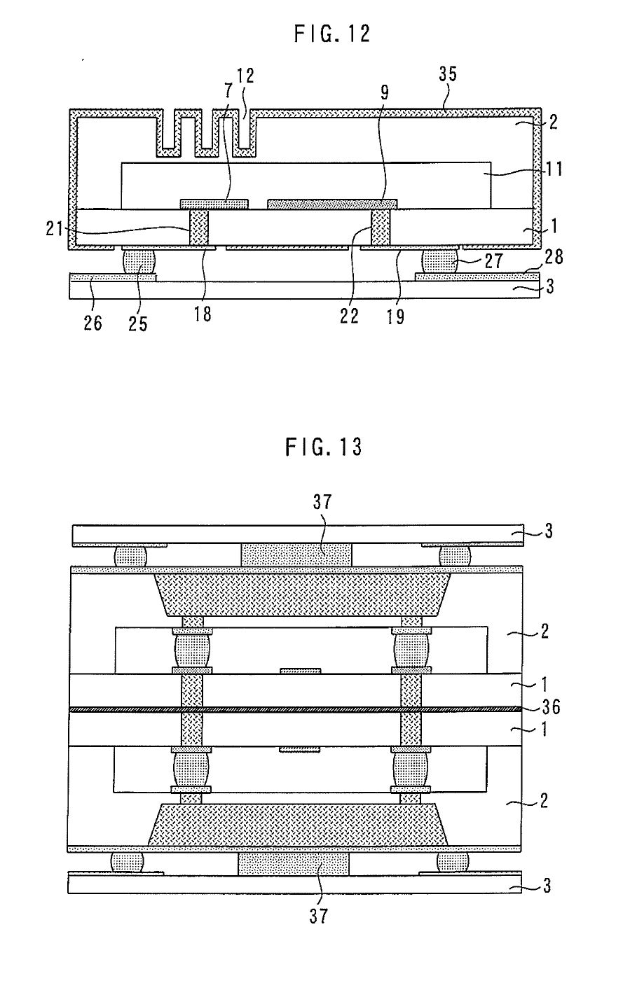

FIG. 12 is a sectional view of a semiconductor device according to a fourth embodiment of the present invention. FIG. 12 corresponds to the sectional view taken along line III-III in FIG. 1. The main body chip 1 and the cap chip 2 are covered with metal film 35, whereby external electromagnetic noise can be blocked.

In the case where chip is covered with the metal film 35, however, there is a possibility of occurrence of unnecessary oscillation in a waveguide mode. Therefore, a plurality of recesses 12 are provided in the cap chip 2 to prevent the formation of a perfect waveguide, thus enabling suppression of unnecessary oscillation in the waveguide mode. Also, the effective surface area is increased. Therefore the effect of releasing heat is also improved. Further, since the need for filling the recess 12 with a metal is eliminated, the time required for the wafer process can be reduced.

In the present embodiment, the plurality of recesses 12 are provided perpendicularly to the gate-drain direction. However, the recesses 12 may alternatively be provided parallel to the gate-drain direction.

### Fifth Embodiment

FIG. 13 is a sectional view showing a semiconductor device according to a fifth embodiment of the present invention. FIG. 13 corresponds to the sectional view taken along line I-I in FIG. 1. Two semiconductor devices according to the first embodiment are prepared and the back surfaces of the main body chips 1 of the two semiconductor devices are joined to each other by an electroconductive bonding agent 36. A heat sink 37 is joined to the metallic member 14.

By joining the two semiconductor devices, the area for the circuit patterns can be reduced to half. Also, since heat can be released through the two surfaces, the effect of releasing heat is improved. Two semiconductor devices according to any one of the second to fourth embodiments may also be joined to each other.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2011-114933, filed on May 23, 2011 including specification, claims, drawings and summary, on which the Convention priority of the present application is based, are incorporated herein by reference in its entirety.

1. A semiconductor device comprising:
a main body chip having a front surface and a back surface;
a circuit pattern on the front surface of the main body chip, the circuit pattern including a first pad;
a cap chip including a front surface and a back surface, a first recess in the front surface of the cap chip, and a second recess in the back surface of the cap chip, the cap chip being joined to the main body chip with the first recess facing the circuit pattern;
a second pad on a bottom surface of the first recess of the cap chip;
a first metallic member inlaid in the second recess of the cap chip;
a first through electrode electrically connecting the second pad to the first metallic member through the cap chip; and
a bump electrically connecting the first pad to the second pad.

2. The semiconductor device according to claim 1, further comprising:
a third pad on the back surface of the main body chip; and
a second through electrode electrically connecting the first pad to the third pad through the cap chip.

3. The semiconductor device according to claim 1, further comprising:
a third recess in the back surface of the cap chip;
a second metallic member inlaid in the third recess of the cap chip; and
a second through electrode electrically connecting the first pad to the second metallic member through the cap chip.

4. The semiconductor device according to claim 1, further comprising a metal film covering the cap chip.

5. A semiconductor device including two semiconductor devices according to claim 1, wherein the back surfaces of the main body chips of the two semiconductor devices are joined to each other.
